(19) United States
(12) Patent Application Publication
(10) Pub. No.: US 2008/0258781 A1
(43) Pub. Date: Oct. 23, 2008

(54) Multi-Bit Programmable Frequency Divider

(75) Inventors: Wenyi Song, San Jose, CA (US); Geertjan Joordens, Sunnyvale, CA (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/994,229

(22) PCT Filed: Jun. 30, 2006
(86) PCT No.: PCT/IB2006/052215

§ 371 Date: Jul. 2, 2008

Related U.S. Application Data
(60) Provisional application No. 60/696,365, filed on Jun. 30, 2005.

(30) Foreign Application Priority Data
Jun. 30, 2006 (IB) PCT/IB2006/052215

(51) Int. Cl. H03B 19/00

(52) U.S. Cl. 327/117

(57) ABSTRACT

A multi-bit, programmable, modular digital frequency divider divides an input frequency by an m-bit integer divisor to produce an output frequency. The integer divisor re-initializes m-number of flip-flop stages with the divisor input at the end of every output clock. Each divisor bit is gated to a D-input through a respective data multiplexer controlled by a clock output. A run/initialize mode controller receives the input frequency and produces the divided output frequency and controls the timing of the re-initialization.

The present invention relates to electronic digital circuitry, and more particularly to multi-bit, programmable frequency dividers.

Digital frequency dividers are used in computer and communications circuits to synthesize various utility clocks from a reference oscillator. A digital frequency divider takes a clock signal “cki” as the input, and outputs a new clock signal “cko”. The frequency of cko is the frequency of cki divided by an integer. Such dividers can be implemented in logic as fixed divisor divide-by-n, or programmable divisor divide-by-m.

Synchronous-type dividers and counters clock all the memory elements in parallel with one clock. Programmable digital frequency dividers can be implemented with finite-state-machines (FSM), e.g., with pencil-and-paper, or using logic synthesis tools such as Synopsys Design Compiler. Direct digital synthesis (DDS) is another method, it uses an accumulator clocked by an input cki. During every input clock cycle, the accumulator adds a fixed integer P to its content. A number P can be selected such that at the end of every N input clock cycles, the accumulator overflows. Thus the overflow output functions as the output “cko” of the frequency divider.

Asynchronous-type dividers and counters use a clock to trigger the first flip-flop in a chain, and then the Q-outputs of previous stages are used to clock the next succeeding stages. For example, ripple, decade, and up-down counters employ asynchronous techniques.

Conventional serial input, parallel load counters have separate load controls that asynchronously load the new count value on the next input clock. The output frequency can jitter as a result because complete output cycles are not guaranteed.

Briefly, a multi-bit, programmable, modular digital frequency divider embodiment of the present invention divides an input frequency by an m-bit integer divisor to produce an output frequency. The integer divisor re-initializes m-number of flip-flop stages with the divisor input at the end of every output clock. Each divisor bit is gated to a D-input through a respective data multiplexer controlled by a clock output. A run/initialize mode controller receives the input frequency and produces the divided output frequency and controls the timing of the re-initialization.

An advantage of the present invention is a programmable digital frequency divider is provided.

A further advantage of the present invention is a digital frequency divider is provided with a 50% duty cycle output for any integer divisor input.

A still further advantage of the present invention is that a divider is provided that can be expanded to m-bits with m-modular stages.

The above and still further objects, features, and advantages of the present invention will become apparent upon consideration of the following detailed description of specific embodiments thereof, especially when taken in conjunction with the accompanying drawings.

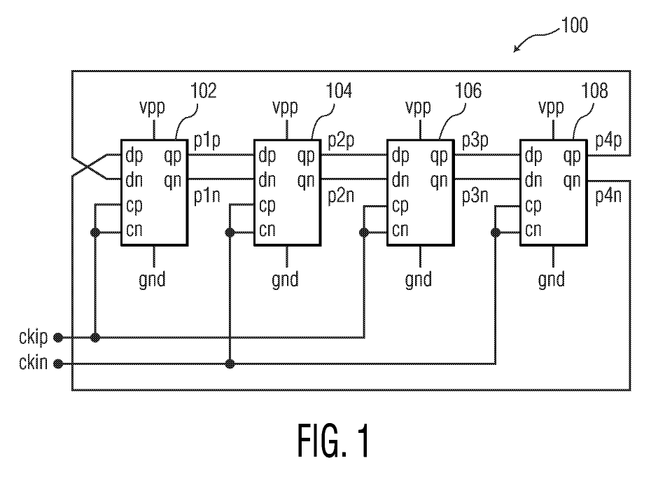

FIG. 1 is a schematic diagram of a three-bit programmable frequency divider embodiment of the present invention;

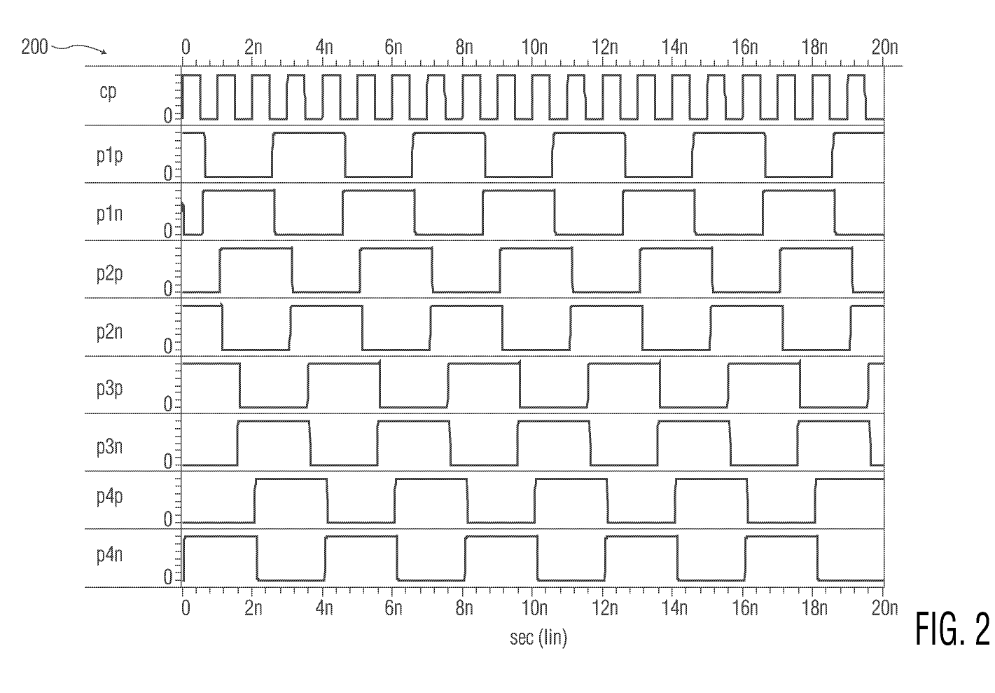

FIG. 2 is a diagram of various key waveforms measured for a prototype implementation of the divider of FIG. 1 set for a divide-by-3;

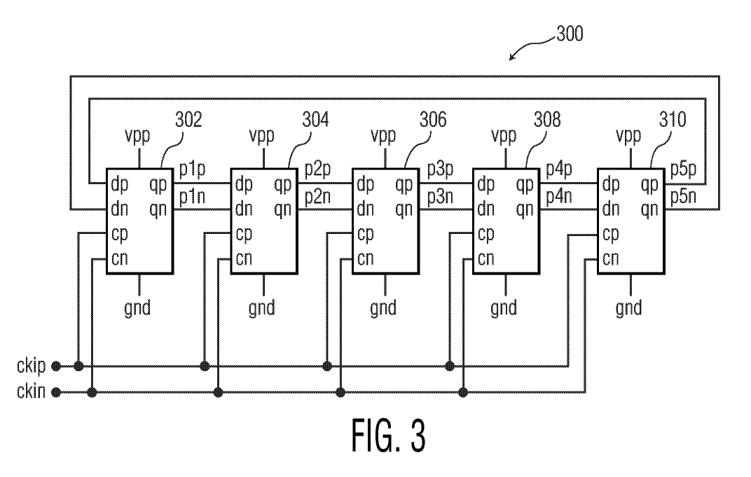

FIG. 3 is a schematic diagram of a three-bit, modular programmable frequency divider embodiment of the present invention;

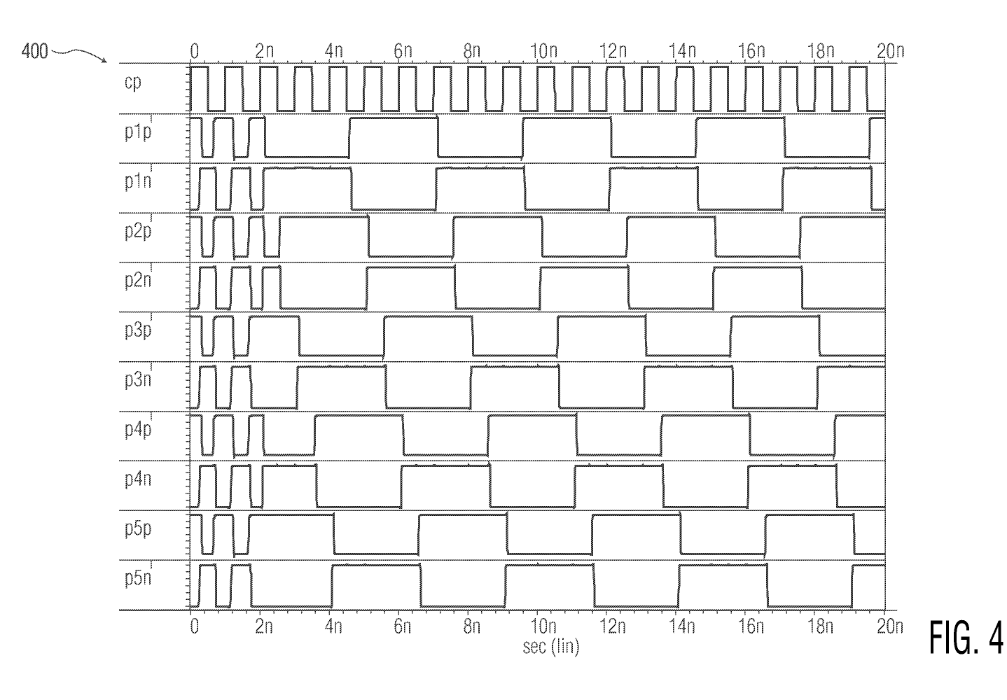

FIG. 4 is a schematic diagram of a three-bit, modular programmable frequency divider embodiment of the present invention;

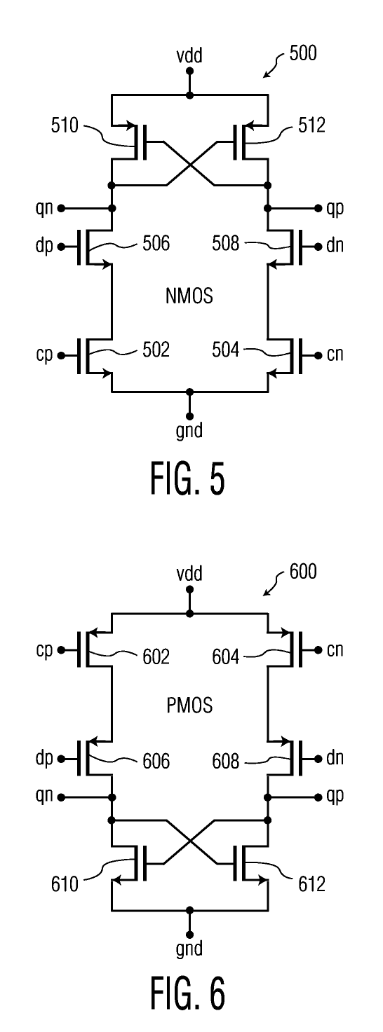

FIG. 5 is a schematic diagram of a three-bit programmable divider embodiment of the present invention with a 50% duty cycle output; and

FIG. 6 is a diagram of various key waveforms measured for a prototype implementation of the divider of FIG. 4 set for a divide-by-3.

FIG. 1 illustrates a three-bit programmable frequency divider embodiment of the present invention, and is referred to herein by the general reference numeral 100. The divider 100 has a clock input “cki”, a clock output “cko”, and M-bit divisor inputs d2, d1, and d0. With more divisor bits, such can provide integer divisions in the range of 2-2M, e.g., a 6-bit divider provides integer divisors 2-64.

The divider 100 uses direct divisor coding, e.g., for the three-bit divider 100 the binary divisor bits are programmable inputs “d2, d1, and d0”. More bits are possible for larger divisors. It should be obvious to an artisan how to expand divisor 100 in FIG. 1 to accommodate more divisor bits with more counting stages.

Divider 100 is implemented in pmos, nmos, or cmos technology digital logic with inverters 101-105, OR-gates 106-17, multiplexers 108-113, and three memory bit element D-type flip-flops 114-117. The data inputs of the multiplexers are labeled “D0” and “D1”. The data input selection signal is “S0”, and the data output is “Z”. Therefore, Z=D0 for S0=0, Z=D1 for S0=1. For D-type flip-flops 114-117, on the rising edge of CP, then QN=0 for D=1, QN=1 for D=0.

The input clock “cki” is connected to the input of inverter 105 and clocks D-type flip-flop 114. The output clock “cko” is buffered from inverter 104 and produced by the Q-output of D-type flip-flop 114. The d2, d1, and d0 three-bit divisor inputs are buffered by inverters 101-103 and connected to the data inputs “D0” of multiplexers (MXD0) 108, (MXD1) 110, and (M×D2) 112, respectively.

Depending on the logic status of cko, the three-bit memory elements, D-type flip-flops 114-117, work in either “run” mode, cko=1, or “initialization” mode, cko=0. For example, in “run” mode they operate like a ripple down counter. FF0 115 is clocked by cki, FF1 116 is clocked by the output of FF0 115, and FF2 117 is clocked by the output of FF1 116. Eventually they will ripple count to where all three Q-outputs are zero, e.g., q0=q1=q2=0. Then the “initialization” mode is entered.

On the next falling edge of “cki”, “qn” from FFN 114 rises to logic-1, and “cko” at the “S0” inputs of all the multiplexers 108-113 drops to logic-0. The multiplexers all then route the divisor inputs d0, d1, and d2 to the D-inputs of flip-flops 115-117. On the sub-sequent rising edge of “cki” the data inputs are latched to the data outputs, e.g., q0=d0, q1=d1, and q2=d2.

Since it is prohibited for all of the divisor input bits to be zero, at least one bit will be a logic-1. The logical-OR of the three d0-d2 bits will always produce a logic-1 at the output of OR-gate 107. This will ripple through OR-gate 106 and set the D-input of FFN 114 to a logic-1. On the subsequent falling edge of “cki”, qn from FFN 114 returns to logic-0, and “cko” returns to logic-1. The FF0-FF2 memory element flip-flops 115-117 return to the “run” mode, and they can ripple count the newest divisor that was loaded.

The “run” mode period will operate for at least one input clock cycle, and at most, seven input clock cycles, depending on states of the three divisor input bits.

FIG. 2 represents a set of signal waveforms 200 for a divider 100 programmed to divide-by-3 (d2=0, d1=1, d0=0).

Extending the three-bit programmable frequency divider to M-bit is straightforward. For each additional bit k, a stage is added that includes a D-type flip-flop FFk, a clock multiplexer MXCk, a data multiplexer MXDk, an inverter Idk, and an OR gate ORQk.

FIG. 3 represents a representative three-bit, fully modular frequency divider embodiment of the present invention, and is referred to herein by the general reference numeral 300. Modular divider 300 comprises a D-type flip-flop (FFN) 302, an inverter 304 to receive an input clock “cki”, and an OR-gate 306. The Q-output (qn) is connected to an inverter 308 which provides output clock “cko”.

A first module 310 includes two one-bit multiplexers (MXD0) 311 and (MXC0) 312. Their Z-outputs are respectively connected to the D-input and clock input of a D-type flip-flop 313. The Q-output (q0) provides the count to a next stage, if any. A NOR-gate 314 provides a final count signal (fc0). A divisor bit input (d0) is connected to inverter 315 which outputs the inverse (f0) to the D0 input of multiplexer 311. To prevent excessive loading of the “cki” and “cko” signal inputs used by the multiplexers, such are buffered before passed along to the next module. A buffer 316 accepts “cki” and drives out a “cki_buf0” for the next module. A buffer 317 accepts “cko” and drives out a “cko_buf0” for the next stage.

A second module 320 is identical to module 310 and includes two one-bit multiplexers (MXD1) 321 and (MXC1) 322. Their Z-outputs are respectively connected to the D-input and clock input of a D-type flip-flop (FF1) 323. The Q-output (q1) provides its count to a next stage, if any. An OR-gate 324 provides a final count signal (fc1). A divisor bit input (d1) is connected to inverter 325 which outputs the inverse (f1) to the D0 input of multiplexer 321. A buffer 326 accepts “cki_buf0” from the previous module, and produces “cki_buf1” for the next one. A buffer 327 accepts “cko_buf0” and drives out a “cko_buf1” for the next module.

A third module 330 is identical to modules 310 and 320, and includes two one-bit multiplexers (MXD2) 331 and (MXC2) 332. Their Z-outputs are respectively connected to the D-input and clock input of a D-type flip-flop (FF2) 333. The Q-output (q2) provides the count to a next stage, if any. An OR-gate 334 provides a final count signal (fc2) that ripples down to OR-gate 306 and FFN 302. A divisor bit input (d2) is connected to inverter 335 which outputs the inverse (f2) to the D0 input of multiplexer 331. A buffer 336 accepts “cki_buf1” from the previous module and drives out a “cki_buf2” for any succeeding module. A buffer 337 similarly accepts a “cko_buf1” from the previous module 320 and drives out a “cko_buf2”.

If the “cki” and “cko” signals were not buffered by each stage, extending the divider, e.g., to 6-bits could exceed the fan-out limits of the original drivers. But if heavy enough buffers were always included for large configurations, they may unnecessarily waste power when in small configurations. Each M-bit configuration may therefore require optimization to find an optimal balance of performance and power consumption.

To achieve a load independent of the value M, two inverters are added in each bit-block. Each signal in this modular configuration has a load independent of the number of bit-blocks in the divider. Such modular configuration allows the designer to optimize the single bit-block at the transistor and layout level, and then simply cascade M bit-blocks to form an M-bit programmable frequency divider.

FIG. 4 represents a representative three-bit, fully modular frequency divider embodiment of the present invention, and is referred to herein by the general reference numeral 400. It improves on the performance of divider 300, but at the expense of necessitating two types of modules, one odd and the other even. Modular divider 400 comprises a D-type flip-flop (FFN) 402, an inverter 404 to receive an input clock “cki”, and a NAND-gate 406. The Q-output (qn) is connected to an inverter 408 which provides output clock “cko”.

A first module 410 is an even-bit type and includes two one-bit multiplexers (MXD0) 411 and (MXC0) 412. Their Z-outputs are respectively connected to the D-input and clock input of a D-type flip-flop 413. The Q-output (q0) provides the count to a next stage, if any. A NOR-gate 414 provides a final count signal (fc0). A divisor bit input (d0) is connected to inverter 415 which outputs the inverse (f0) to the D0 input of multiplexer 411. An inverter 416 accepts “cki” and produces “cki_buf0” for the data inputs (D0, D1) of the multiplexer 412. Inverters 417 and 418 accepts “cko” and produces “cko_buf0i” for the selector inputs (S0) of both the multiplexers.

A second module 420 is an odd-bit type includes two one-bit multiplexers (MXD1) 421 and (MXC1) 422. Their Z-outputs are respectively connected to the D-input and clock input of a D-type flip-flop (FF1) 423. The Q-output (q1) provides the count to a next stage, if any. A NAND-gate 424 provides a final count signal (fc1). A divisor bit input (d1) is connected to inverter 425 which outputs the inverse (f1) to the D0 input of multiplexer 421. An inverter 426 accepts “cki_buf0” and produces “cki_buf1” for the data input (D0) of multiplexer 422. Inverter 427 accepts “cko_buf0” and produces “cko_buf1” for the selector inputs (S0) of both multiplexers 421 and 422.

A third module 430 is also an even-bit type and includes two one-bit multiplexers (MXD2) 431 and (MXC2) 432. Their Z-outputs are respectively connected to the D-input and clock input of a D-type flip-flop (FF2) 433. The Q-output (q2) provides the count to a next stage, if any. A NOR-gate 434 provides a final count signal (fc2). A divisor bit input (d2) is connected to inverter 435 which outputs the inverse (f2) to the D0 input of multiplexer 431. An inverter 436 accepts “cki_buf1” and produces “cki_buf2” for the data input (D0) of multiplexer 432. Inverters 437 and 438 accept “cko_buf1” from the previous stage 420 and produce “cko_buf2i” for the selector inputs (S0) of both multiplexers 431 and 432.

Additional divisor bits can be accommodated by adding additional odd and even modular bit blocks as shown in the example of FIG. 4. It is possible to make all the stages them same, regardless of even-bit or odd-bit types if the cumulative propagation delays through fc2, fc1, fc0, to the D-input of FFN 402 are not a problem. Otherwise, the particular digital logic semiconductor technology being used for logic-gates 406, 414, 424, and 434.

Divider 400 uses different odd and even modular bit blocks to reduce overall propagation delays. A NOR gate 414, 434 is used in the even bit blocks, and a NAND gate 424 in odd bit blocks. In CMOS technology, OR gates use two inversion stages and therefore impose two propagation delays. NOR and NAND gates can be implemented in CMOS with only a single inversion stage. The result is that the propagation delay between the q0 and D input of FFN 402 is cut in half, thus allowing much higher “cki” input frequencies to be accepted for programmable division.

Dividers 100, 300, and 400, do not have “cko” outputs with 50% duty cycles. If a 50% duty cycle output is important, divider 500 of FIG. 5 represents a solution.

A 50% duty cycle three-bit programmable divider embodiment of the present invention is illustrated in FIG. 5, and is referred to herein by the general reference numeral 500. For any divisor input d0, d1, d2, the divider 500 will always produce a “cko50” output with a 50/50 duty cycle from the output of R-S flip-flop 502.

Divider 500 further comprises D-type flip-flops 504-408, one-bit data multiplexers 510-516, OR-gates 518-521, NAND-gate 522, XOR-gates 524-527, AND-gates 528-530, and inverters 532-537.

The “qn” output of FFN 505 is negated and buffered by inverter 537 to produce a non-50% duty cycle “cko”. Such controls the run/initialize mode of the three counter stages grouped around FF0 506, FF1 507, and FF2 508. The selector inputs of multiplexers MXD0 511, MXC0 512, MXD1 513, MXC0 514, MXD2 515, and MXC2 516 are toggled to allow either the loading of the divisor d0-d2 (f0-f2) into the flip-flops 506-508 on the next clock, or the overflow count from the previous stage.

The “cko” signal has the correct output frequency division, but not necessarily the desired 50% duty cycle. So the logic formed by NAND-gate 522, XOR-gates 524-527, and AND-gates 528-530 is used in combination with the d0-d2 inputs to determine when the R-S latch 502 should toggle clear. The “cko” signal, and its inverted form “qn”, are used by multiplexer 510 and flip-flop 504 to set R-S latch 502 according to the state of d0. Other combinatorial logic could be used to achieve the same result, e.g., a 50% duty cycle “cko50”.

The modular, expandable construction of divider 500 should be obvious to an artisan on inspection of FIG. 5. Divider 500 can be expanded to handle practically any divisor of m-bits.

FIG. 6 illustrates several waveforms obtained at key points in a test of a prototype implementation of divider 500, “cko50” represents an output with a 50% duty cycle.

Although particular embodiments of the present invention have been described and illustrated, such is not intended to limit the invention. Modifications and changes will no doubt become apparent to those skilled in the art, and it is intended that the invention only be limited by the scope of the appended claims.

What is claimed is:

1. A multi-bit, programmable, modular digital frequency divider for dividing an input frequency by an m-bit integer divisor to produce divided output frequency, wherein m-number of flip-flop stages are re-initialized with a divisor input at the completion of every output clock, and wherein each divisor bit is gated to a memory element through a respective data multiplexer controlled by a clock output, and wherein, a run/initialize mode controller is provided to receive said input frequency and produce a divided output frequency and to control timing of said re-initialization.

2. A multi-bit, programmable frequency divider, comprising: a run/initialize mode controller having a divider clock input “cki” and for producing a divider clock output “cko”; a plurality of m-number of flip-flop stages configured in a ring and each having a clock input, a D-input, and a Q-output; a corresponding plurality of m-number of data selectors connected to alternatively gate either a Q-output or divisor bit input to a D-input of a respective flip-flop stage according to said divider clock output “cko”; a corresponding plurality of m-number of clock selectors connected to alternatively gate either said divider clock input “cki” or previous stage's Q-output to a clock-input of a respective flip-flop stage according to said divider clock output “cko”.

3. The divider of claim 2, further comprising: a 50% duty cycle output “cko50” that is synchronized to said a divider clock output “cko”.

4. The divider of claim 2, further comprising: an output latch providing for a 50% duty cycle output “cko50” that is controlled by said a divider clock output “cko” and triggered by said divider clock input “cki”.

5. The divider of claim 2, further comprising: a modular construction wherein individual ones of the plurality of m-number of flip-flop stages, and the corresponding plurality of m-number of data, and corresponding plurality of m-number of clock selectors, are arranged in m-number of modules, and each produces a combinatorial signal for output cycle completion to the run/initialize mode controller.

6. The divider of claim 2, further comprising: a modular construction wherein individual ones of the plurality of m-number of flip-flop stages, and the corresponding plurality of m-number of data, and corresponding plurality of m-number of clock selectors, are arranged in m-number of modules in two types depending on its use as an odd-bit or even-bit stage, and every module produces a combinatorial signal for output cycle completion having only one gate propagation delay contribution to the run/initialize mode controller.
